(19) United States
(12) Patent Application Publication
(10) Pub. No.: US 2010/0171206 A1
(43) Pub. Date: Jul. 8, 2010

(54) Package-on-Package Device, Semiconductor Package, and Method for Manufacturing The Same

(76) Inventors: Chi-Chih Chu, Shiaugang Chiu (TW); Cheng-Yi Weng, Kaohsiung City (TW)

Correspondence Address: COOLEY LLP;ATTN: Patent Group, Suite 1100, 777 - 6th Street, NW, WASHINGTON, DC, 20001, US

(21) Appl. No.: 12/544,560

(22) Filed: Aug. 20, 2009

Related U.S. Application Data
(63) Continuation-in-part of application No. 12/507,305, filed on Jul. 22, 2009.

(30) Foreign Application Priority Data
Jan. 7, 2009 (TW) 98100325

(51) Int. Cl. H01L 23/538; H01L 21/56

(52) U.S. Cl. 257/686; 438/124; 257/E23.169; 257/E21.502

(57) ABSTRACT

A semiconductor package includes: (1) a substrate including an upper surface and a lower surface opposite to the upper surface; (2) a chip mounted and electrically connected to the upper surface of the substrate; (3) an interposer mounted on the chip and electrically connected to the upper surface of the substrate, the interposer including an upper surface and a lower surface that is opposite to the upper surface and facing the chip, the interposer including a plurality of electrical contacts located on the upper surface of the interposer; and (4) a molding compound sealing the substrate, the interposer, and the chip, and exposing the lower surface of the substrate, the molding compound defining a plurality of holes that enclose and expose respective ones of the electrical contacts.

### CROSS REFERENCE TO RELATED APPLICATIONS

This application is a continuation-in-part of U.S. application Ser. No. 12/507,305, filed on Jul. 22, 2009, which claims the benefit of Taiwan Application Serial No. 98100325, filed on Jan. 7, 2009, the disclosures of which are incorporated herein by reference in their entireties.

### FIELD OF THE INVENTION

The present invention generally relates to a package-on-package device and, more particularly, to a bottom package of a package-on-package device including a molding compound that has holes enclosing and exposing electrical contacts.

### BACKGROUND

Currently, a package-on-package (hereinafter referred as “POP”) device is related to a semiconductor package disposed on another semiconductor package. The basic object of the POP device is to increase the density of components so as to result in more functions of components per unit volume and better regional efficiency. Thus, the total area of the POP device can be decreased, and the cost is reduced simultaneously.

Referring to FIG. 1, a conventional POP device 50, i.e., a two-layer multi-package module (“MPM”), is shown in which interconnections are made by solder balls 28. In this POP device 50, a first package is the “top” package 20, and a second package is the “bottom” package 10. The top package 20 is stacked on the bottom package 10.

However, a lower molding compound 17 of the bottom package 10 of the conventional POP device 50 lacks any hole enclosing and exposing pads 11 or the solder balls 28. Thus, the conventional POP device 50 typically cannot reduce the solder extrusion risk after soldering, and further typically cannot reduce the possibility of a short circuit. Also, manufacturing of the conventional POP device 50 can suffer from undesirably low stacking yields, as the solder balls 28 may not sufficiently adhere to the pads 11 of the bottom package 10 during reflow. This inadequate adherence can be exacerbated by molding operations used to form the bottom package 10, as the molding compound 17 can be prone to overflowing onto and contaminating the pads 11 of substrate 12. Moreover, because of the reduced lateral extent of the molding compound 17 relative to an area of the substrate 12, the conventional POP device 50 can be prone to bending or warping, which can create sufficient stresses on the solder balls 28 that lead to connection failure.

Referring to FIG. 2, another conventional POP device 150 is shown. The POP device 150 includes a top package 120 and a bottom package 110. The conventional POP device 150 is substantially similar to the conventional POP device 50, where the similar components are designated with similar reference numerals. The difference between the conventional POP devices 50 and 150 is that the top package 120 of the conventional POP device 150 includes solder balls 128, which are disposed on pads located on a lower surface of a substrate 122 for electrically connecting to pads 115 of a chip 114 of the bottom package 110. The pads 115 can be referred as a circuit layer that can be formed by photolithography and etching processes of a redistribution layer (“RDL”). The solder balls 128 of the top package 120 are inserted into the bottom package 110, and are electrically connected to the pads 115, thereby forming the interconnections between the top and bottom packages 120 and 110 of the conventional POP device 150.

However, a lower molding compound 117 of the bottom package 110 of the conventional POP device 150 lacks any hole enclosing and exposing the pads 115 or the solder balls 128. Thus, the conventional POP device 150 typically cannot reduce the solder extrusion risk after soldering, and further typically cannot reduce the possibility of a short circuit. Also, manufacturing of the conventional POP device 150 can suffer from undesirably low stacking yields, as the solder balls 128 may not sufficiently adhere to the pads 115 of the bottom package 110 during reflow. This inadequate adherence can be exacerbated by molding operations used to form the bottom package 110, as the molding compound 117 can be prone to overflowing onto and contaminating the pads 115. Moreover, because of the reduced lateral extent of the molding compound 117 relative to an area of a substrate 112 of the bottom package 110, the conventional POP device 150 can be prone to bending or warping, which can create sufficient stresses on the solder balls 128 that lead to connection failure.

Accordingly, there exists a need for a POP device capable of solving the above-mentioned problems.

### SUMMARY

Certain embodiments of the invention provide a POP device including a top package and a bottom package. The bottom package includes a first chip mounted and electrically connected to an upper surface of a first substrate. A first molding compound seals the first substrate and the first chip and exposes a lower surface of the first substrate, wherein the first molding compound includes a plurality of holes, each of which encloses and exposes a respective electrical contact located on the upper surface of the first substrate. The top package is stacked on the bottom package, and includes a second substrate, a second chip, and a second molding compound. The second substrate has an upper surface and a lower surface opposite to the upper surface, and the lower surface is electrically connected to the electrical contacts of the first substrate. The second chip is mounted and electrically connected to the upper surface of the second substrate. The second molding compound seals the second substrate and the second chip and exposes the lower surface of the second substrate.

According to the POP device of certain embodiments of the invention, the first molding compound of the bottom package has the holes that enclose and expose the electrical contacts of the first substrate of the bottom package, thereby reducing the solder extrusion risk after soldering, and further reducing the possibility of a short circuit. Furthermore, the holes enclose the electrical contacts of the first substrate, and, thus, a pre-solder or a solder ball of each electrical contact of the first substrate can be positioned so as to improve stacking yields and avoid or reduce the package offset between the top and bottom packages after soldering.

The foregoing, as well as additional objects, features, and advantages of embodiments of the invention, will be more apparent from the following detailed description, which proceeds with reference to the accompanying drawings.

### BRIEF DESCRIPTION OF THE DRAWINGS

FIG. 1 is a cross-sectional view of a conventional POP device.

FIG. 2 is a cross-sectional view of another conventional POP device.

FIG. 3 is a cross-sectional view of a POP device according to an embodiment of the present invention.

FIG. 4 is a cross-sectional view of a POP device according to another embodiment of the present invention.

FIG. 5 through FIG. 9 are cross-sectional views of a method for manufacturing a bottom package of the POP device of FIG. 3.

FIG. 10 is a cross-sectional view of a POP device according to another embodiment of the present invention.

FIG. 11 is a cross-sectional view of a POP device according to another embodiment of the present invention.

FIG. 12 through FIG. 16 are cross-sectional views of a method for manufacturing a bottom package of the POP device of FIG. 10.

FIG. 17 is a cross-sectional view of a method for manufacturing a bottom package of a POP device according to another embodiment of the present invention.

FIG. 18 is a cross-sectional view of a method for manufacturing a bottom package of a POP device according to another embodiment of the present invention.

FIG. 19 and FIG. 20 are cross-sectional views of a method for manufacturing a bottom package of a POP device according to another embodiment of the present invention.

FIG. 21 and FIG. 22 are cross-sectional views of a method for manufacturing a bottom package of a POP device according to another embodiment of the present invention.

FIG. 23 is a side view of a POP device according to another embodiment of the present invention.

FIG. 24 is a side view of a POP device according to another embodiment of the present invention.

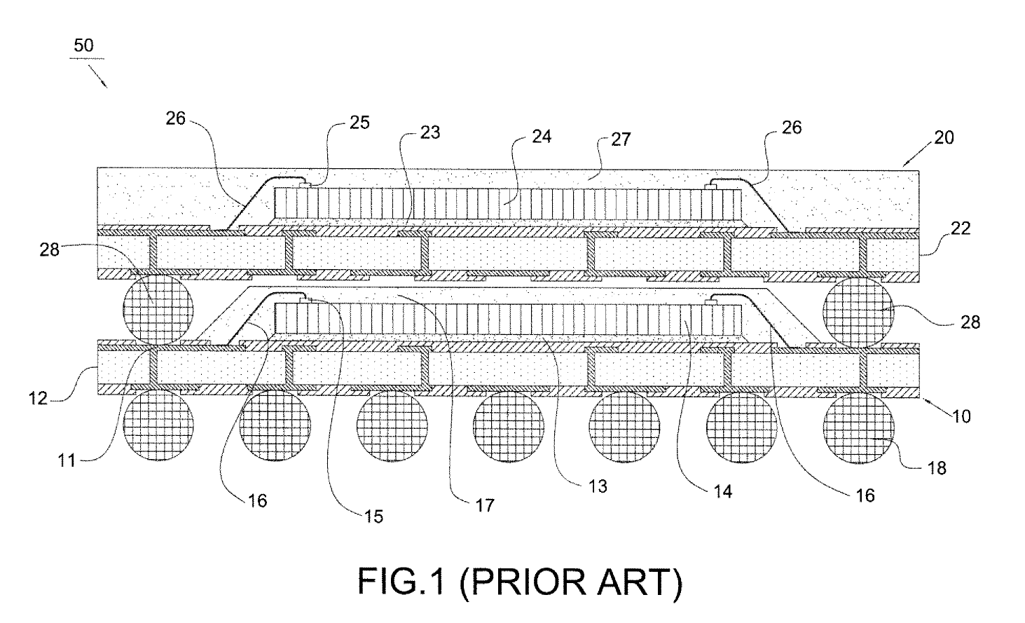

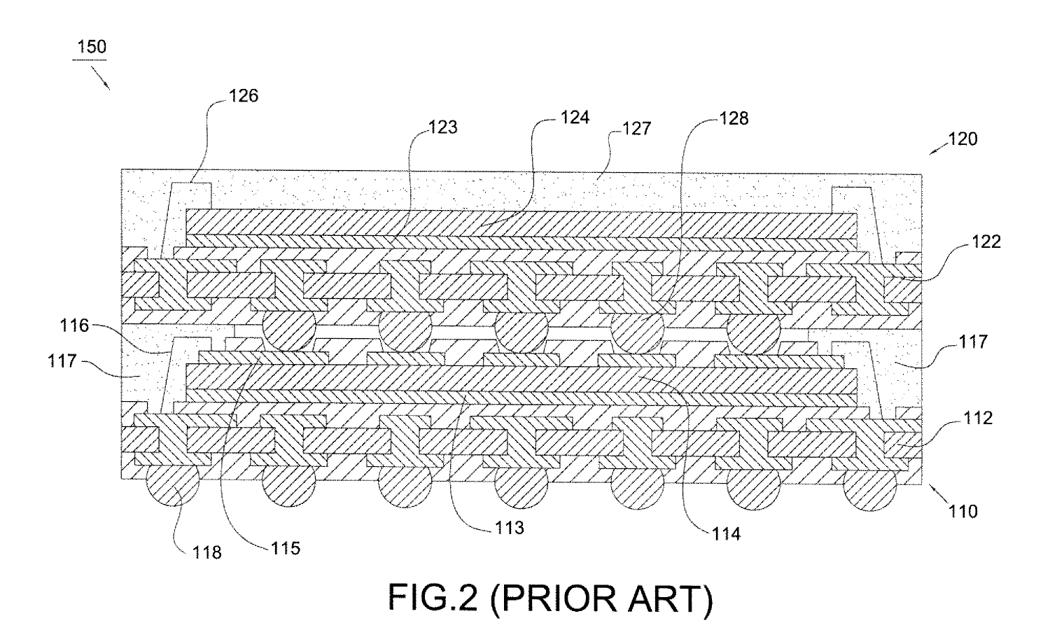

### DETAILED DESCRIPTION

### Definitions

The following definitions apply to some of the aspects described with respect to some embodiments of the invention. These definitions may likewise be expanded upon herein.

As used herein, the singular terms “a,” “an,” and “the” include plural referents unless the context clearly dictates otherwise. Thus, for example, reference to a chip can include multiple chips unless the context clearly dictates otherwise.

As used herein, the term “set” refers to a collection of one or more components. Thus, for example, a set of chips can include a single chip or multiple chips. Components of a set also can be referred as members of the set. Components of a set can be the same or different. In some instances, components of a set can share one or more common characteristics.

As used herein, the term “adjacent” refers to being near or adjoining. Adjacent components can be spaced apart from one another or can be in actual or direct contact with one another. In some instances, adjacent components can be connected to one another or can be formed integrally with one another.

As used herein, relative terms, such as “inner,” “interior,” “outer,” “exterior,” “top,” “bottom,” “upper,” “upwardly,” “lower,” “downwardly,” “vertical,” “vertically,” “lateral,” “laterally,” “above,” and “below,” refer to an orientation of a set of components with respect to one another, such as in accordance with the drawings, but do not require a particular orientation of those components during manufacturing or use.

As used herein, the terms “connect,” “connected,” “connecting,” and “connection” refer to an operational coupling or linking. Connected components can be directly coupled to one another or can be indirectly coupled to one another, such as via another set of components.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing operations described herein.

As used herein, the terms “electrically conductive” and “electrical conductivity” refer to an ability to transport an electric current. Electrically conductive materials typically correspond to those materials that exhibit little or no opposition to flow of an electric current. One measure of electrical conductivity is in terms of Siemens per meter (“S·m⁻¹”). Typically, an electrically conductive material is one having a conductivity greater than about 10⁴ S·m⁻¹, such as at least about 10⁵ S·m⁻¹ or at least about 10⁶ S·m⁻¹. Electrical conductivity of a material can sometimes vary with temperature. Unless otherwise specified, electrical conductivity of a material is defined at room temperature.

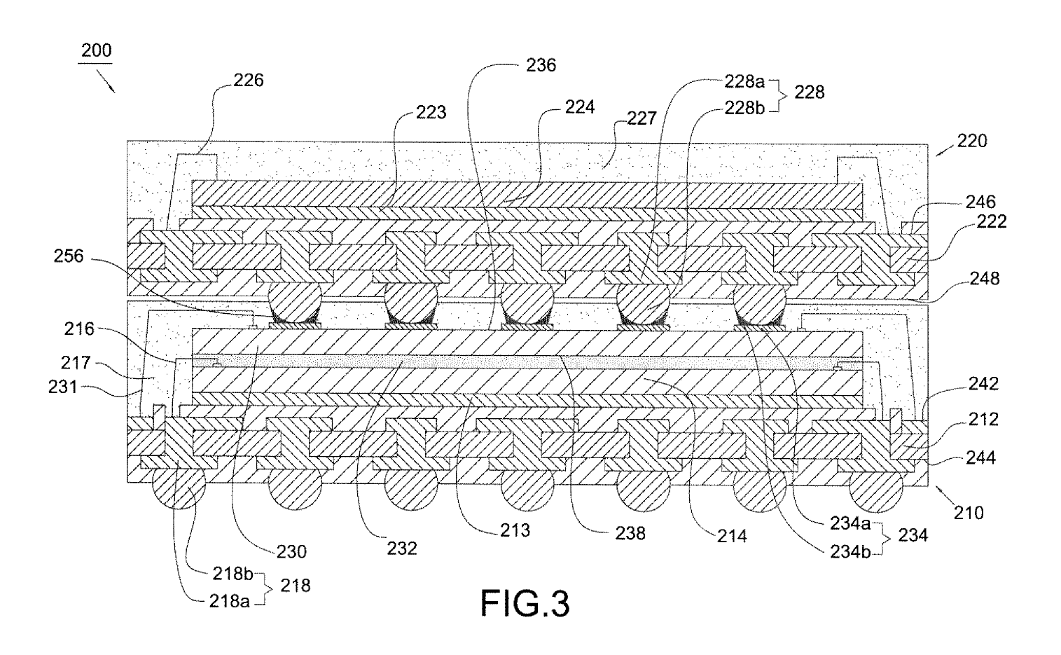

Referring to FIG. 3, a POP device 200 is shown in accordance with an embodiment of the present invention. The POP device 200 is a two-layer MPM, and includes a top package 220 and a bottom package 210.

The bottom package 210 includes a first chip 214 mounted and electrically connected to an upper surface 242 of a first substrate 212. While the single chip 214 is shown in FIG. 3, it is contemplated that multiple chips can be included within the bottom package 210, and can be arranged in a stacked fashion. The first substrate 212 has upper and lower metal layers, which can be patterned to provide appropriate circuitry and electrically connected by way of vias. An interposer 230 is mounted on the first chip 214 by an adhesive, such as a film-on-wire layer, and is electrically connected to the upper surface 242 of the first substrate 212. The interposer 230 can be a circuit board or a substrate. The interposer 230 has an upper surface 236 and a lower surface 238. The lower surface 238 is opposite to the upper surface 236 and faces the first chip 214. The interposer 230 includes a plurality of electrical contacts 234 located on the upper surface 236 of the interposer 230. In this embodiment, each electrical contact 234 includes a pad 234a and a pre-solder 234b disposed on the pad 234a. Or, in another embodiment, each electrical contact 234 includes the pad 234a and a solder ball (not shown) disposed on the pad 234a. It is also contemplated that each electrical contact 234 can include the pad 234a and a conductive bump disposed on the pad 234a and formed from any suitable electrically conductive material. A plurality of bonding wires 231 are adapted to electrically connect the interposer 230 to the upper surface 242 of the first substrate 212. A first molding compound 217 seals the first substrate 212, the first chip 214, the interposer 230, and the bonding wires 231 and exposes a lower surface 244 of the first substrate 212. Furthermore, the first molding compound 217 includes a plurality of through-holes 256, which each encloses and exposes a respective electrical contact 234. The cross-section of each through-hole 256 is tapered, e.g., the cross-section of the through-hole 256 is cone or funnel-shaped so as to have a wider upper portion and a narrower lower portion. Also, the depth of each through-hole 256, relative to the height of a respective electrical contact 234, is such that an upper end of the electrical contact 234 is recessed below an upper surface of the first molding compound 217, whereby the through-holes 256 have more capacity for accommodating a solder, e.g., a pre-solder or a solder ball, during stacking. It is also contemplated that the upper end of each electrical contact 234 can be coplanar with or can protrude above the upper surface of the first molding compound 217. It is further contemplated that the interposer 230 can be optionally omitted, and that the through-holes 256 can each enclose and expose a respective electrical contact of the first chip 214. In the illustrated embodiment, the bottom package 210 is implemented so as to have a fan-in configuration, in which the electrical contacts 234 are distributed in an array and located in a central portion of the upper surface 236 of the interposer 230, and the through-holes 256 are distributed in a corresponding array and located in a corresponding, central portion of the upper surface of the first molding compound 217. This fan-in configuration can support a larger number of interconnections between the top and bottom packages 220 and 210, and can allow greater flexibility in accommodating chips of varying designs.

The top package 220 is stacked on the bottom package 210. The top package 220 includes a second chip 224 mounted and electrically connected to an upper surface 246 of a second substrate 222. While the single chip 224 is shown in FIG. 3, it is contemplated that multiple chips can be included within the top package 220, and can be arranged in a stacked fashion. A lower surface 248 of the second substrate 222 is electrically connected to the electrical contacts 234 of the interposer 230. The second substrate 222 of the top package 220 also has upper and lower metal layers, which can be patterned to provide appropriate circuitry and electrically connected by way of vias. A second molding compound 227 seals the second substrate 222 and the second chip 224, and exposes the lower surface 248 of the second substrate 222.

According to the bottom package 210 and the top package 220 in this embodiment, the first and second chips 214 and 224 are mounted on the upper surfaces 242 and 246 of the first and second substrates 212 and 222 by adhesives 213 and 223 (e.g., die attach epoxy), respectively. Also, the first and second chips 214 and 224 are electrically connected to the upper surfaces 242 and 246 of the first and second substrates 212 and 222 by bonding wires 216 and 226, respectively. The bonding wires 216 and 226 are also sealed by the first and second molding compounds 217 and 227, respectively. Or, in another embodiment, the first and second chips 214 and 224 are bonded to the upper surfaces 242 and 246 of the first and second substrates 212 and 222 by conductive bumps (not shown), respectively.

A plurality of electrical contacts 228 (e.g., a combination of solder balls 228b and pads 228a) are mounted on the lower surface 248 of the second substrate 222 for electrically connecting to the electrical contacts 234 of the interposer 230 of the bottom package 210. Thus, the interconnections between the top and bottom packages 220 and 210 of the POP device 200 are achieved, such as by merging or fusing respective pairs of the solder balls 228b and the pre-solders 234b during reflow. A plurality of electrical contacts 218 (e.g., a combination of solder balls 218b and pads 218a) are mounted on the lower surface 244 of the first substrate 212 for electrically connecting to an external circuit board (not shown).

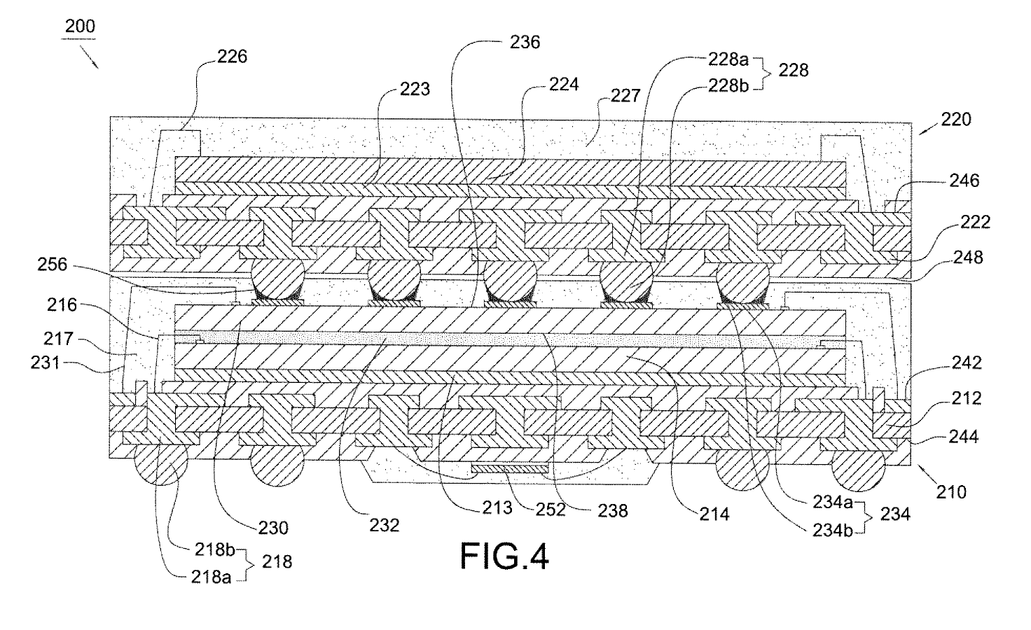

Referring to FIG. 4, in another embodiment, a third chip 252 can be mounted and electrically connected to the lower surface 244 of the first substrate 212 by way of a wire bonding process or a flip chip bonding process, thereby providing more functions of components per unit volume and better regional efficiency.

According to the POP device 200 of the embodiments of FIG. 3 and FIG. 4, the first molding compound 217 of the bottom package 210 has the through-holes 256, which each encloses and exposes a respective electrical contact 234 of the interposer 230 of the bottom package 210, thereby reducing the solder extrusion risk after soldering, and further reducing the possibility of a short circuit. Also, the through-holes 256 enclose the electrical contacts 234 of the interposer 230, and, thus, a pre-solder or a solder ball of each electrical contact 234 of the interposer 230 can be positioned so as to improve stacking yields and avoid or reduce the package offset between the top and bottom packages 220 and 210 after soldering. Also, molding operations used to form the bottom package 210 can be simplified and carried out to improve stacking yields, as the first molding compound 217 need not be molded with a reduced lateral extent. As a result of the enhanced lateral extent of the first molding compound 217 relative to an area of the first substrate 212, the POP device 200 has improved structural rigidity, and is less prone to bending or warping.

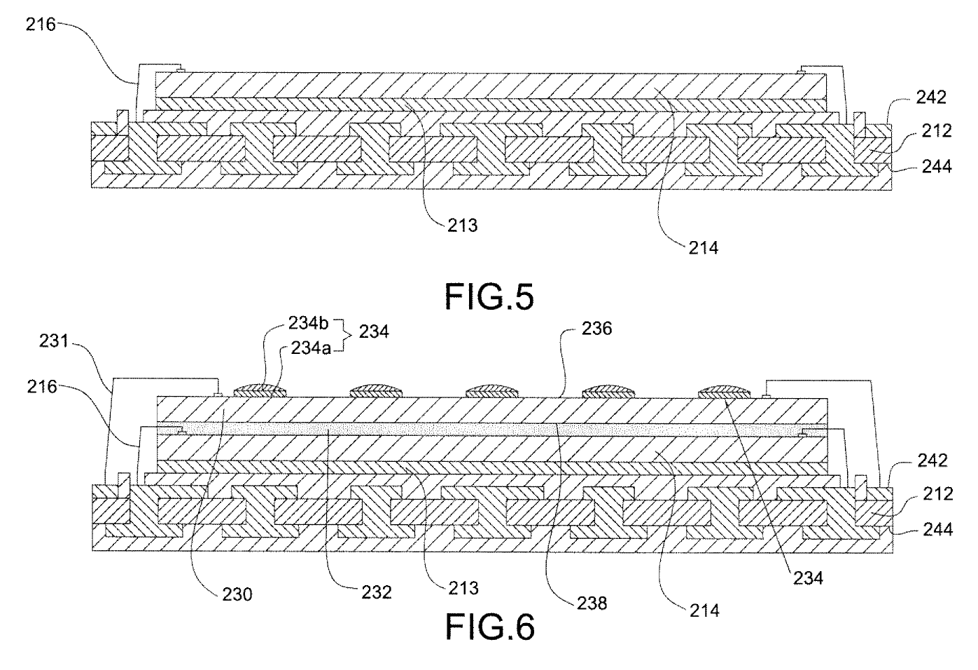

FIG. 5 through FIG. 9 show a method for manufacturing the bottom package 210 of the POP device 200 of the embodiment of FIG. 3. It is contemplated that a similar method can be used for manufacturing the bottom package 210 of the embodiment of FIG. 4. Referring to FIG. 5, a substrate 212 is provided, wherein the substrate 212 has an upper surface 242 and a lower surface 244 opposite to the upper surface 242. In this embodiment, a chip 214 can be mounted to the upper surface 242 of the substrate 212 by an adhesive 213, and electrically connected to the upper surface 242 of the substrate 212 by a plurality of bonding wires 216.

Referring to FIG. 6, an interposer 230 is mounted on the chip 214 and electrically connected to the substrate 212, wherein the interposer 230 has an upper surface 236 and a lower surface 238, and the lower surface 238 is opposite to the upper surface 236 and faces the chip 214. The interposer 230 includes a plurality of electrical contacts 234 located on the upper surface 236 of the interposer 230. In this embodiment, each electrical contact 234 includes a pad 234a and a pre-solder 234b disposed on the pad 234a. Or, in another embodiment, each electrical contact 234 includes the pad 234a and a solder ball (not shown) disposed on the pad 234a. The interposer 230, along with the pre-solders 234b (or solder balls), can be mounted on the chip 214. Or, the interposer 230 can be initially mounted on the chip 214, and then the pre-solders 234b (or solder balls) can be mounted on the pads 234a. Then, a plurality of bonding wires 231 are provided for electrically connecting the interposer 230 to the upper surface 242 of the substrate 212.

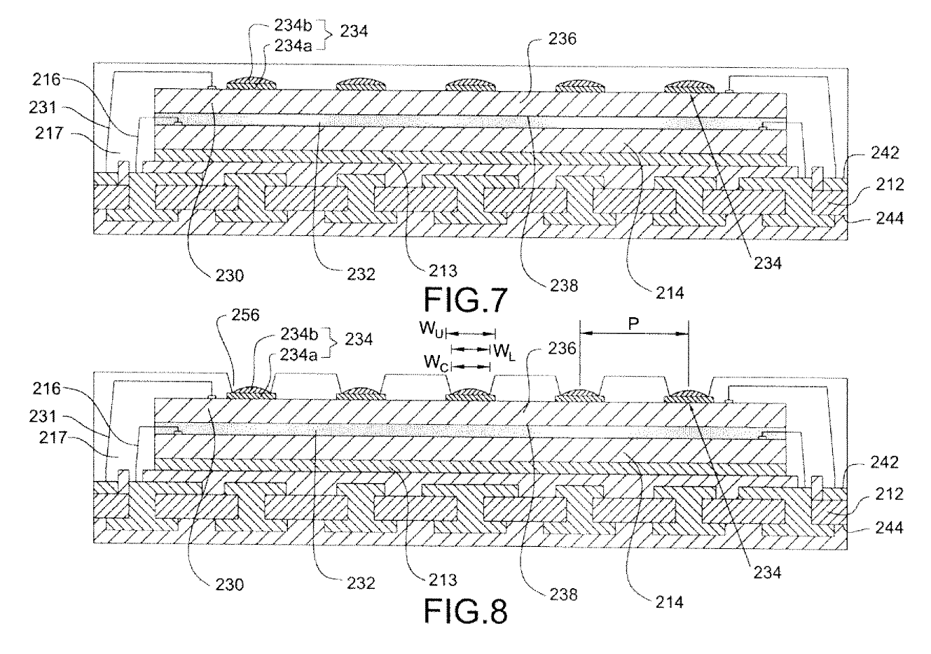

Referring to FIG. 7, a molding compound 217 is applied or molded for sealing the substrate 212, the chip 214, the interposer 230, and the bonding wires 216 and 231, and exposing the lower surface 244 of the substrate 212. For certain implementations, molding can be carried out by a typical mold (i.e., a mold that is not specially made). Referring to FIG. 8, a plurality of through-holes 256 are formed in the molding compound 217 by a drilling process (e.g., a laser drilling process, a mechanical drilling process, or a chemical drilling process), thereby exposing the electrical contacts 234 of the interposer 230. For example, a laser drilling process can be carried out using a laser, such as a green laser, an infrared laser, a solid-state laser, or a CO₂ laser. The laser can be implemented as a pulsed laser or a continuous wave laser. Suitable selection and control over operating parameters of the laser allow control over sizes and shapes of the through-holes 256. For certain implementations, a peak output wavelength of the laser can be selected in accordance with a particular composition of the molding compound 217, and, for some implementations, the peak output wavelength can be in the visible range or the infrared range. Also, an operating power of the laser can be in the range of about 3 Watts (“W”) to about 20 W, such as from about 3 W to about 15 W or from about 3 W to about 10 W. In the case of a pulsed laser implementation, a pulse frequency and a pulse duration are additional examples of operating parameters that can be suitably selected and controlled.

Still referring to FIG. 8, each through-hole 256 is shaped in the form of a circular cone or a circular funnel, including a substantially circular opening with a width that varies along a vertical direction. In particular, a lateral boundary of each through-hole 256 tapers towards a respective electrical contact 234, and contacts the electrical contact 234 to define a lower end of the through-hole 256. However, it is contemplated that the shapes of the through-holes 256, in general, can be the same or different, and can be any of a number of shapes. For example, each through-hole 256 can have another type of tapered shape, such as an elliptical cone shape, a square cone shape, or a rectangular cone shape, a non-tapered shape, such as a circular cylindrical shape, an elliptic cylindrical shape, a square cylindrical shape, or a rectangular cylindrical shape, or another regular or irregular shape. It is also contemplated that a lateral boundary of each through-hole 256 can be curved in a convex fashion, curved in a concave fashion, or roughly textured.

For certain implementations, an upper width W_{U} of each through-hole 256, namely a lateral extent adjacent to an upper end of the through-hole 256 and adjacent to an upper surface of the molding compound 217, can be in the range of about 250 micrometer (“μm”) to about 650 μm, such as from about 300 μm to about 600 μm or from about 350 μm to about 550 μm, and a lower width W_{L} of each through-hole 256, namely a lateral extent adjacent to a lower end of the through-hole 256, can be in the range of about 90 μm to about 500 μm, such as from about 135 μm to about 450 μm or from about 180 μm to about 400 μm. If the through-hole 256 has a non-uniform shape, the upper width W_{U} or the lower width W_{L} can correspond to, for example, an average of lateral extents along orthogonal directions. Also, the upper width W_{U} of each through-hole 256 can be greater than the lower width W_{L} of the through-hole 256, with a ratio of the upper width W_{U} and the lower width W_{L} corresponding to an extent of tapering and represented as follows: W_{U}=aW_{L}, where a is in the range of about 1.1 to about 1.7, such as from about 1.2 to about 1.6 or from about 1.3 to about 1.5. Alternatively, or in conjunction, the upper width W_{U} and the lower width W_{L} can be represented relative to a width W_{C} of a respective pre-solder 234b (or solder ball) as follows: W_{U}>W_{C} and W_{C}≧W_{L}≧bW_{C}, where b sets a lower bound for the lower width W_{L}, and can be, for example, about 0.8, about 0.85, or about 0.9. For certain implementations, an upper bound for the upper width W_{U} can be represented as follows: P≧W_{U}>W_{C}, where P corresponds to a distance between centers of nearest-neighbor electrical contacts 234, which distance is also sometimes referred as an interconnection pitch. For certain implementations, the interconnection pitch P can be in the range of about 300 μm to about 800 μm, such as from about 350 μm to about 650 μm, from about 400 μm to about 600 μm, from about 300 μm to about 500 μm, or from about 300 μm to about 400 μm. By setting the upper bound for the upper width W_{U} in such fashion, the through-holes 256 can be sufficiently sized, while retaining lateral walls of the molding compound 217 that are disposed between the through-holes 256.

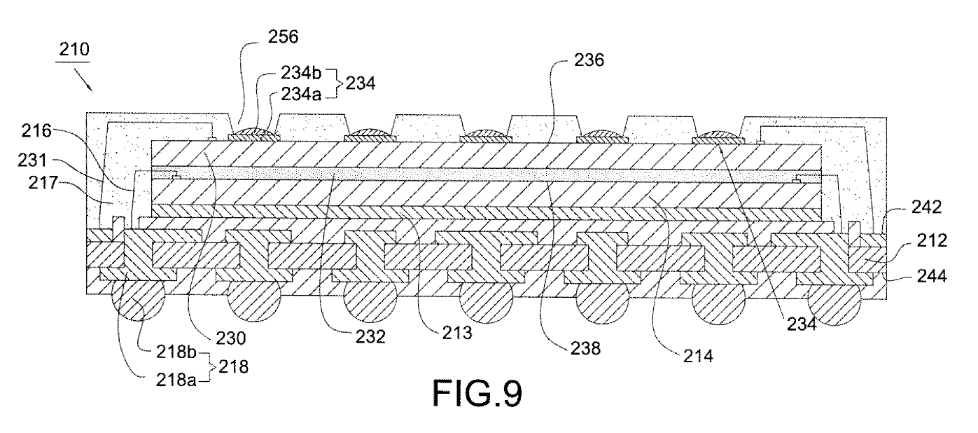

Referring to FIG. 9, a plurality of solder balls 218b are mounted on pads 218a located on the lower surface 244 of the substrate 212 so as to form the bottom package 210 having a fan-in configuration. It is contemplated that the method described with reference to FIG. 5 through FIG. 9 can be carried out sequentially or in parallel using an array of substrates, which are subsequently subjected to singulation to form the bottom package 210.

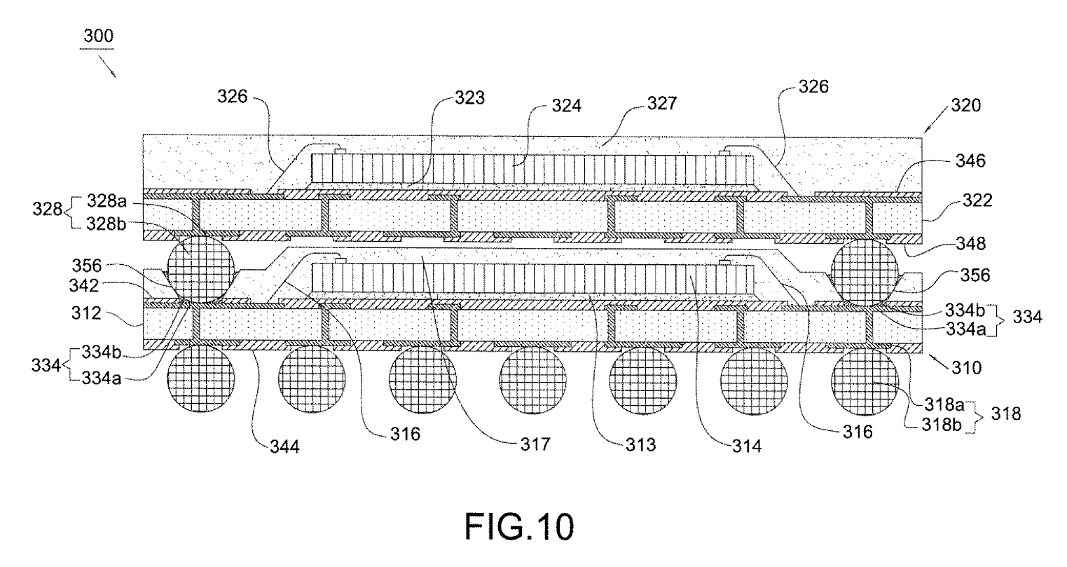

Referring to FIG. 10, a POP device 300 is shown in accordance with another embodiment of the present invention. The POP device 300 is a two-layer MPM, and includes a top package 320 and a bottom package 310.

The bottom package 310 includes a first chip 314 mounted and electrically connected to an upper surface 342 of a first substrate 312. While the single chip 314 is shown in FIG. 10, it is contemplated that multiple chips can be included within the bottom package 310, and can be arranged in a stacked fashion. The first substrate 312 has upper and lower metal layers, which can be patterned to provide appropriate circuitry and electrically connected by way of vias. The first substrate 312 includes a plurality of electrical contacts 334 located on the upper surface 342 of the first substrate 312. In this embodiment, each electrical contact 334 includes a pad 334a and a pre-solder 334b disposed on the pad 334a. Or, in another embodiment, each electrical contact 334 includes the pad 334a and a solder ball (not shown) disposed on the pad 334a. It is also contemplated that each electrical contact 334 can include the pad 334a and a conductive bump disposed on the pad 334a and formed from any suitable electrically conductive material. A first molding compound 317 seals the first substrate 312 and the first chip 314 and exposes a lower surface 344 of the first substrate 312. Furthermore, the first molding compound 317 includes a plurality of through-holes 356, which each encloses and exposes a respective electrical contact 334. The cross-section of each through-hole 356 is tapered, e.g., the cross-section of the through-hole 356 is cone or funnel-shaped so as to have a wider upper portion and a narrower lower portion. Also, the depth of each through-hole 356, relative to the height of a respective electrical contact 334, is such that an upper end of the electrical contact 334 is recessed below an upper surface of the first molding compound 317, whereby the through-holes 356 have more capacity for accommodating a solder, e.g., a pre-solder or a solder ball, during stacking. It is also contemplated that the upper end of each electrical contact 334 can be coplanar with or can protrude above the upper surface of the first molding compound 317. In the illustrated embodiment, the bottom package 310 is implemented so as to have a fan-out configuration, in which the electrical contacts 334 are distributed in one or more rows and located in a peripheral portion of the upper surface 342 of the first substrate 312, and the through-holes 356 are distributed in one or more corresponding rows and located in a corresponding, peripheral portion of the first molding compound 317.

The top package 320 is stacked on the bottom package 310. The top package 320 includes a second chip 324 mounted and electrically connected to an upper surface 346 of a second substrate 322. While the single chip 324 is shown in FIG. 10, it is contemplated that multiple chips can be included within the top package 320, and can be arranged in a stacked fashion. A lower surface 348 of the second substrate 322 is electrically connected to the electrical contacts 334 of the first substrate 312. The second substrate 322 of the top package 320 also has upper and lower metal layers, which can be patterned to provide appropriate circuitry and electrically connected by way of vias. A second molding compound 327 seals the second substrate 322 and the second chip 324, and exposes the lower surface 348 of the second substrate 322.

According to the bottom package 310 and the top package 320 in this embodiment, the first and second chips 314 and 324 are mounted on the upper surfaces 342 and 346 of the first and second substrates 312 and 322 by adhesives 313 and 323 (e.g., die attach epoxy), respectively. Also, the first and second chips 314 and 324 are electrically connected to the upper surfaces 342 and 346 of the first and second substrates 312 and 322 by bonding wires 316 and 326, respectively. The bonding wires 316 and 326 are also sealed by the first and second molding compounds 317 and 327, respectively. Or, in an another embodiment, the first and second chips 314 and 324 are bonded to the upper surfaces 342 and 346 of the first and second substrates 312 and 322 by conductive bumps (not shown), respectively.

A plurality of electrical contacts 328 (e.g., a combination of solder balls 328b and pads 328a) are mounted on the lower surface 348 of the second substrate 322 for electrically connecting to the electrical contacts 334 of the first substrate 312 of the bottom package 310. Thus, the interconnections between the top and bottom packages 320 and 310 of the POP device 300 are achieved, such as by merging or fusing respective pairs of the solder balls 328b and the pre-solders 334b during reflow. A plurality of electrical contacts 318 (e.g., a combination of solder balls 318b and pads 318a) are mounted on the lower surface 344 of the first substrate 312 for electrically connecting to an external circuit board (not shown).

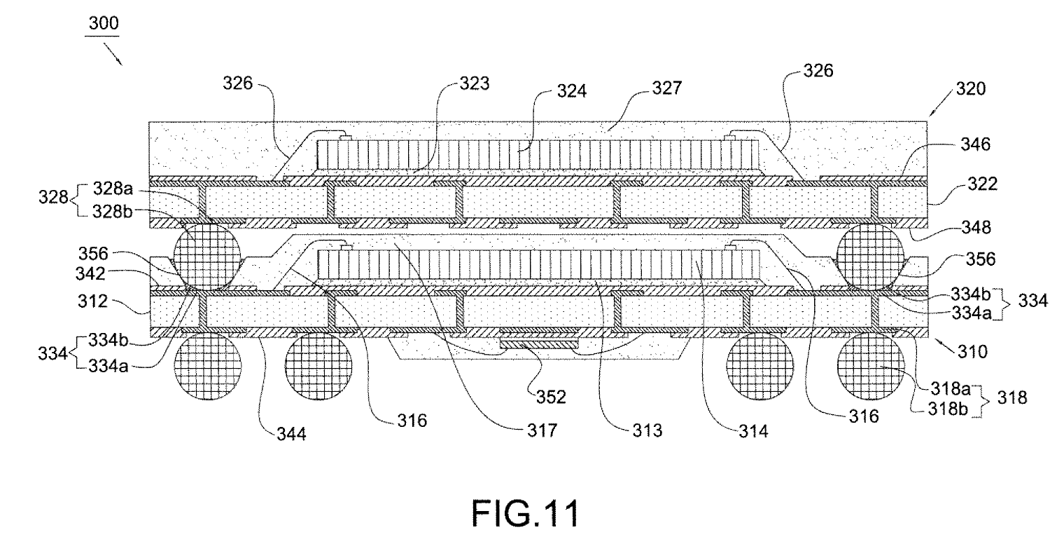

Referring to FIG. 11, in another embodiment, a third chip 352 can be mounted and electrically connected to the lower surface 344 of the first substrate 312 by way of a wire bonding process or a flip chip bonding process, thereby providing more functions of components per unit volume and better regional efficiency.

According to the POP device 300 of the embodiments of FIG. 10 and FIG. 11, the first molding compound 317 of the bottom package 310 has the through-holes 356, which each encloses and exposes a respective electrical contact 334 of the substrate 312 of the bottom package 310, thereby reducing the solder extrusion risk after soldering, and further reducing the possibility of a short circuit. Also, the through-holes 356 enclose the electrical contacts 334 of the first substrate 312, and thus a pre-solder or a solder ball of each electrical contact 334 of the substrate 312 can be positioned so as to improve stacking yields and avoid or reduce the package offset between the top and bottom packages 320 and 310 after soldering. Also, molding operations used to form the bottom package 310 can be simplified and carried out to improve stacking yields, as the first molding compound 317 need not be molded with a reduced lateral extent. As a result of the enhanced lateral extent of the first molding compound 317 relative to an area of the first substrate 312, the POP device 300 has improved structural rigidity, and is less prone to bending or warping.

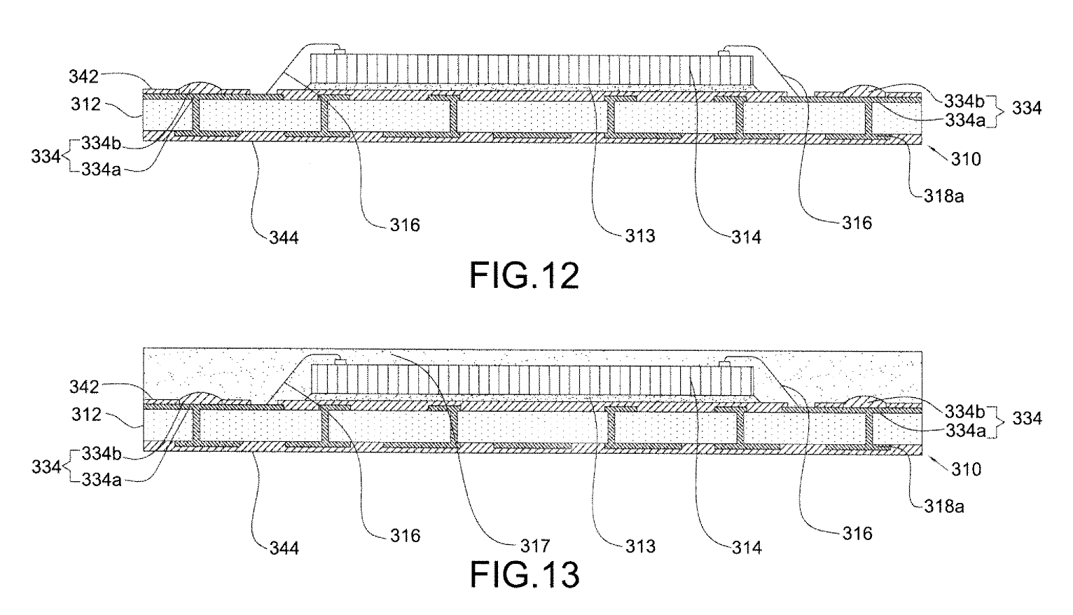

FIG. 12 through FIG. 16 show a method for manufacturing the bottom package 310 of the POP device 300 of the embodiment of FIG. 10. It is contemplated that a similar method can be used for manufacturing the bottom package 310 of the embodiment of FIG. 11. Referring to FIG. 12, a substrate 312 is provided, wherein the substrate 312 has an upper surface 342 and a lower surface 344 opposite to the upper surface 342. The substrate 312 includes a plurality of electrical contacts 334 located on the upper surface 342 of the substrate 312. In this embodiment, each electrical contact 334 includes a pad 334a and a pre-solder 334b disposed on the pad 334a. Or, in another embodiment, each electrical contact 334 includes the pad 334a and a solder ball (not shown) disposed on the pad 334a. A chip 314 can be mounted to the upper surface 342 of the substrate 312 by an adhesive 313, and electrically connected to the upper surface 342 of the substrate 312 by a plurality of bonding wires 316.

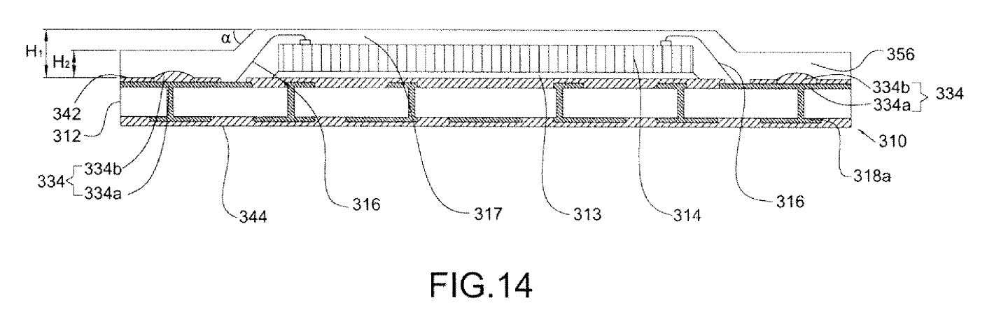

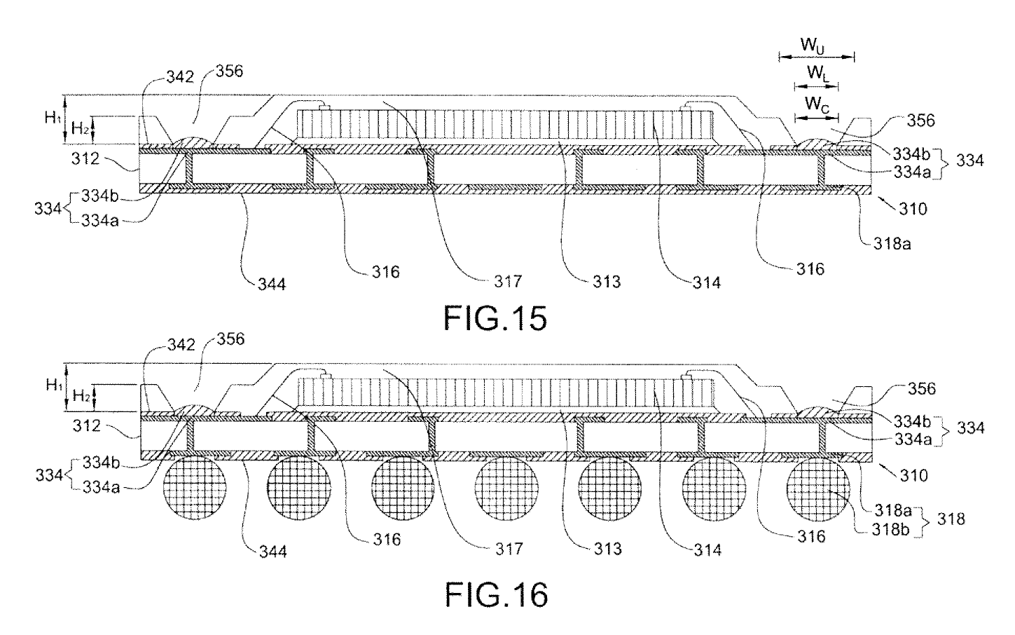

Referring to FIG. 13, a molding compound 317 is applied or molded, thereby sealing the substrate 312 and the chip 314 and exposing the lower surface 344 of the substrate 312. For certain implementations, molding can be carried out by a typical mold (i.e., a mold that is not specially made). Referring to FIG. 14, the thickness of the molding compound 317 at its periphery and located above the electrical contacts 334 is decreased from H₁ to H₂ by a thickness-decreasing process, e.g., a laser thickness-decreasing process, a mechanical thickness-decreasing process, a chemical thickness-decreasing process, or other removal process. As a result, the molding compound 317 is formed with a trapezoid-like shape by the thickness-decreasing process, in which an interface portion between H₁ and H₂ defines an angle α, relative to a horizontal plane, that is in the range of about 20° to about 90°, such as from about 30° to about 90° or from about 45° to about 90°. Referring to FIG. 15, a plurality of through-holes 356 are formed in the molding compound 317 by a drilling process (e.g., a laser drilling process), thereby exposing the electrical contacts 334 of the substrate 312. For example, a laser drilling process can be carried out in a similar fashion as previously described with reference to FIG. 8, and the resulting through-holes 356 can be similarly sized and shaped (e.g., with an upper width W_{U} and a lower width W_{L} that can be represented relative to a width W_{C} of a respective pre-solder 334b (or solder ball)) as previously described with reference to FIG. 8. Since the thickness of the molding compound 317 is decreased from H₁ to H₂, the laser drilling process can be readily carried out on the molding compound 317 to expose the electrical contacts 334 of the substrate 312, whereby the electrical contacts 334 are readily connected to electrical contacts of a top package for improved stacking yields.

Referring to FIG. 16, a plurality of solder balls 318b are mounted on pads 318a located on the lower surface 344 of the substrate 312 so as to form the bottom package 310 having a fan-out configuration. It is contemplated that the method described with reference to FIG. 12 through FIG. 16 can be carried out sequentially or in parallel using an array of substrates, which are subsequently subjected to singulation to form the bottom package 310.

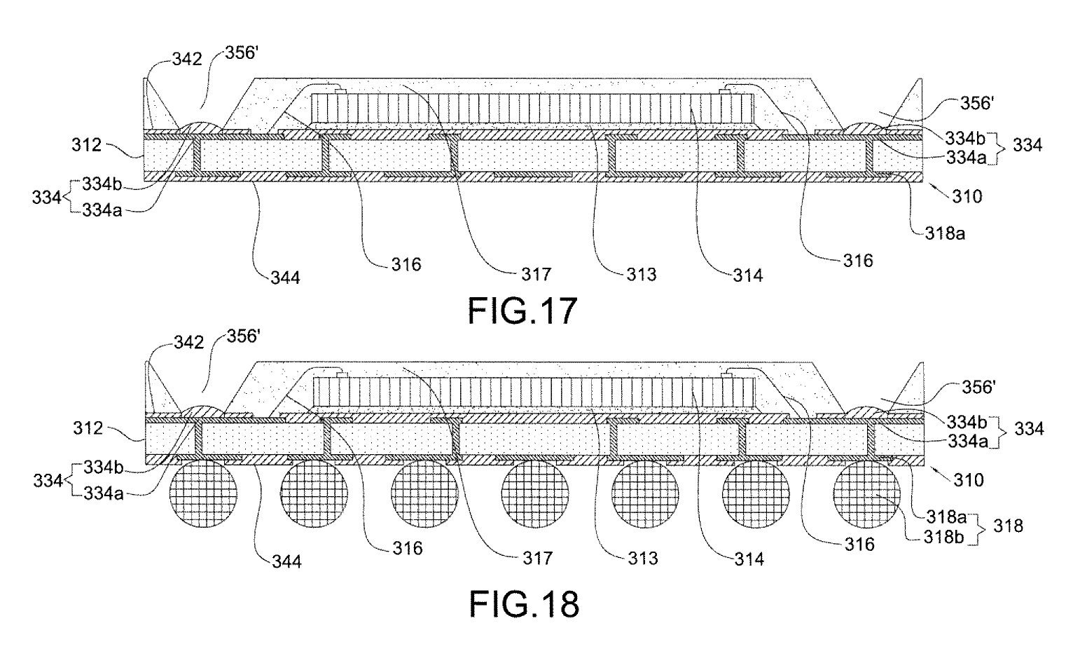

In another embodiment, a molding compound 317 seals a substrate 312 and a chip 314 and exposes a lower surface 344 of the substrate 312, as shown in FIG. 13. Next, referring to FIG. 17, a plurality of through-holes 356′ are formed in the molding compound 317 by a drilling process (e.g., a laser drilling process), thereby exposing electrical contacts 334 of the substrate 312. Then, the thickness of the molding compound 317 located above the electrical contacts 334 is decreased from H₁ to H₂ by a thickness-decreasing process, as previously described with reference to FIG. 14, and the substrate 312 is subjected to solder ball mounting, as previously described with reference to FIG. 16, so as to form a bottom package 310 having a fan-out configuration.

In another embodiment, a plurality of through-holes 356′ are formed in a molding compound 317 by a drilling process (e.g., a laser drilling process), thereby exposing electrical contacts 334 of a substrate 312, as shown in FIG. 17. Since the thickness of the molding compound 317 is not decreased from H₁ to H₂ in this embodiment, the through-holes 356′ have a greater depth so as to have more capacity for accommodating a solder after soldering. Referring to FIG. 18, a plurality of solder balls 318b are mounted on pads 318a located on a lower surface 344 of the substrate 312 so as to form a bottom package 310 having a fan-out configuration.

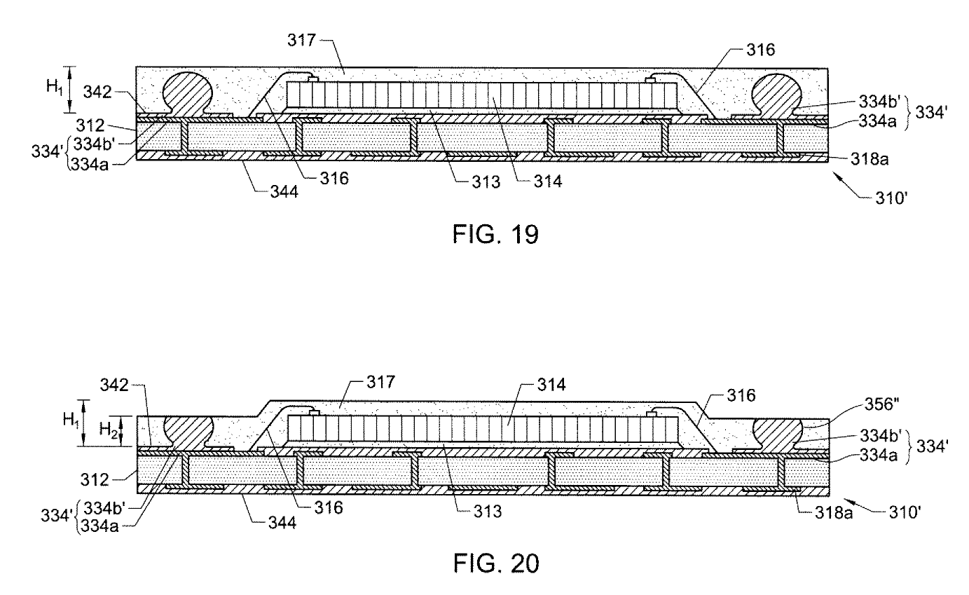

In another embodiment, a molding compound 317 seals a substrate 312, a chip 314, and bonding wires 316 and exposes a lower surface 344 of the substrate 312, as shown in FIG. 19. The molding compound 317 also seals a plurality of electrical contacts 334′, which are located on an upper surface 342 of the substrate 312. In this embodiment, each electrical contact 334′ includes a pad 334a and a solder ball 334b′ disposed on the pad 334a. Each solder ball 334b′ initially has a substantially spherical or spheroidal shape, although other shapes are also contemplated. It is also contemplated that each electrical contact 334′ can include the pad 334a and a conductive bump disposed on the pad 334a and formed from any suitable electrically conductive material. As shown in FIG. 19, the thickness of the molding compound 317 above the electrical contacts 334′, as represented by H₁, is greater than the height of each electrical contact 334′.

Next, referring to FIG. 20, the thickness of the molding compound 317 located above the electrical contacts 334′ is decreased from H₁ to H₂ by a thickness-decreasing process, as previously described with reference to FIG. 14. As a result, a plurality of through-holes 356″ are formed in the molding compound 317, thereby exposing the electrical contacts 334′ of the substrate 312. In this embodiment, the thickness-decreasing process is carried out such that the height of each electrical contact 334′ is decreased by a certain amount, with an upper end of the electrical contact 334′ being substantially coplanar with an upper surface of the molding compound 317 at its periphery. For example, H₂ can be no greater than about ⅔ of H₁, such as from about 1/10 to about ⅔ of H₁ or from about 1/10 to about ½ of H₁, such that the height of each electrical contact 334′ is decreased by a desired amount to result in a substantially hemispherical shape. The substrate 312 is next subjected to solder ball mounting, as previously described with reference to FIG. 16, so as to form a bottom package 310′ having a fan-out configuration. Certain aspects of the bottom package 310′ can be implemented in a similar fashion as described in the co-pending and co-owned Patent Application Publication Nos. 2008/0076208 and 2008/0073769, the disclosures of which are incorporated herein by reference in their entireties.

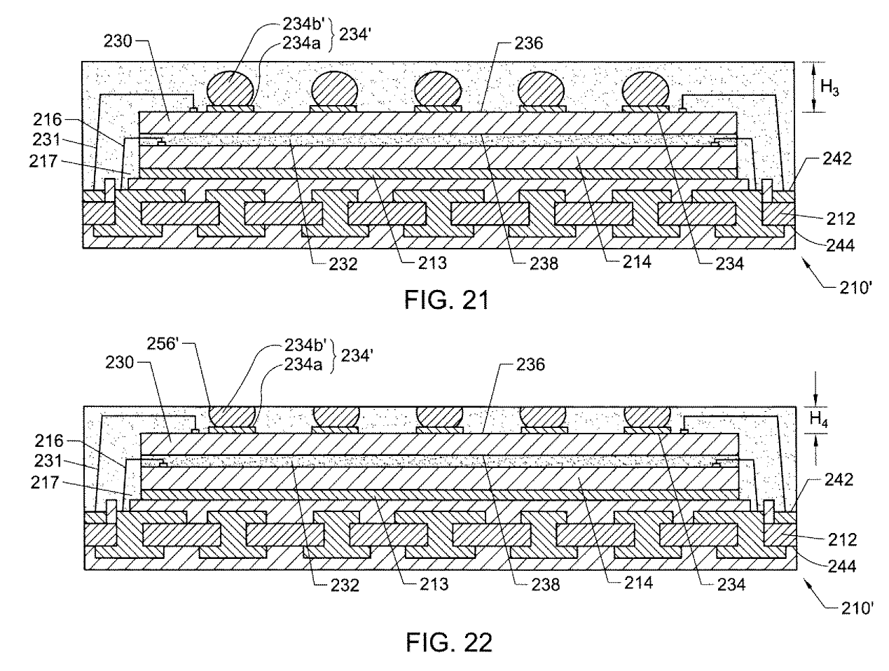

In another embodiment, a molding compound 217 seals a substrate 212, a chip 214, an interposer 230, and bonding wires 216 and 231 and exposes a lower surface 244 of the substrate 212, as shown in FIG. 21. The molding compound 217 also seals a plurality of electrical contacts 234′, which are located on an upper surface 236 of the interposer 230. In this embodiment, each electrical contact 234′ includes a pad 234a and a solder ball 234b′ disposed on the pad 234a. Each solder ball 234b′ initially has a substantially spherical or spheroidal shape, although other shapes are also contemplated. It is also contemplated that each electrical contact 234′ can include the pad 234a and a conductive bump disposed on the pad 234a and formed from any suitable electrically conductive material. As shown in FIG. 21, the thickness of the molding compound 217 above the electrical contacts 234′, as represented by H₃, is greater than the height of each electrical contact 234′.

Next, referring to FIG. 22, the thickness of the molding compound 217 located above the electrical contacts 234′ is decreased from H₃ to H₄ by a thickness-decreasing process, e.g., a laser thickness-decreasing process, a mechanical thickness-decreasing process, a chemical thickness-decreasing process, or other removal process. As a result, a plurality of through-holes 256′ are formed in the molding compound 217, thereby exposing the electrical contacts 234′ of the interposer 230. In this embodiment, the thickness-decreasing process is carried out across substantially the entire upper surface of the molding compound 217, although it is contemplated that the thickness-decreasing process can be carried out within a central portion of the molding compound 217, thereby forming a cavity or a depression surrounded by a periphery of the molding compound 217. Also, the thickness-decreasing process is carried out such that the height of each electrical contact 234′ is decreased by a certain amount, with an upper end of the electrical contact 234′ being substantially coplanar with the upper surface of the molding compound 217. For example, H₄ can be no greater than about ⅔ of H₃, such as from about 1/10 to about ⅔ of H₃ or from about 1/10 to about ½ of H₃, such that the height of each electrical contact 234′ is decreased by a desired amount to result in a substantially hemispherical shape. The substrate 212 is next subjected to solder ball mounting, as previously described with reference to FIG. 9, so as to form a bottom package 210′ having a fan-in configuration.

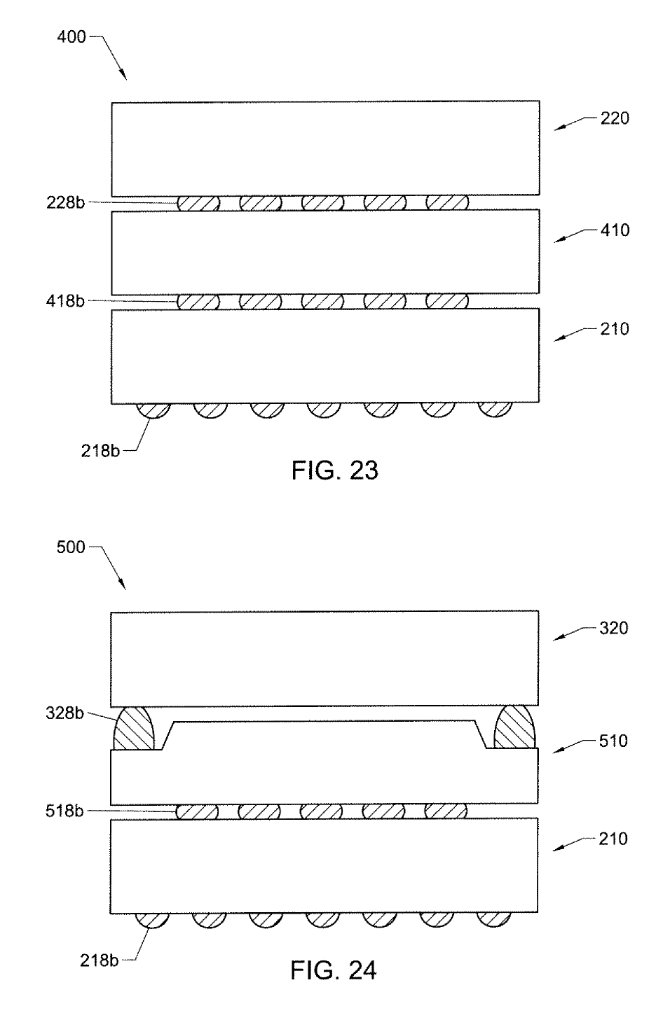

FIG. 23 is a side view of a POP device 400 in accordance with another embodiment of the present invention. The POP device 400 is a three-layer MPM, and includes a top package 220, a middle package 410, and a bottom package 210. Certain aspects of the POP device 400 can be implemented as previously described above, and, thus, are omitted in FIG. 23 for ease of presentation. While three packages are shown in FIG. 23, it is contemplated that more or less packages can be included.

Referring to FIG. 23, the bottom package 210 is implemented with a fan-in configuration as previously described with reference to FIG. 3 through FIG. 9. This fan-in configuration is desirable for the bottom package 210 so as to support a larger number of interconnections within the POP device 400, thereby allowing an increase in the density of components so as to result in more functions of components per unit volume and better regional efficiency. A plurality of solder balls 218b are mounted on a lower surface of the bottom package 210 for electrically connecting to an external circuit board (not shown). It is also contemplated that the package 210′, as previously described with reference to FIG. 21 and FIG. 22, can be used in place of the bottom package 210.

The middle package 410 is stacked on the bottom package 210, and is implemented with a fan-in configuration like that of the bottom package 210, except that a plurality of solder balls 418b are arranged and mounted on a lower surface of the middle package 410 for forming interconnections with the bottom package 210. It is also contemplated that the middle package 410 can be implemented with a fan-in configuration as previously described with reference to the package 210′ of FIG. 21 and FIG. 22. As with the bottom package 210, this fan-in configuration is desirable for the middle package 410 so as to support a larger number of interconnections within the POP device 400. The top package 220 is stacked on the middle package 410, and is implemented as previously described with reference to FIG. 3. A plurality of solder balls 228b are arranged and mounted on a lower surface of the top package 220 for forming interconnections with the middle package 410.

FIG. 24 is a side view of a POP device 500 in accordance with another embodiment of the present invention. The POP device 500 is a three-layer MPM, and includes a top package 320, a middle package 510, and a bottom package 210. Certain aspects of the POP device 500 can be implemented as previously described above, and, thus, are omitted in FIG. 24 for ease of presentation. While three packages are shown in FIG. 24, it is contemplated that more or less packages can be included.

Referring to FIG. 24, the bottom package 210 is implemented with a fan-in configuration as previously described with reference to FIG. 3 through FIG. 9. This fan-in configuration is desirable for the bottom package 210 so as to support a larger number of interconnections within the POP device 500. A plurality of solder balls 218b are mounted on a lower surface of the bottom package 210 for electrically connecting to an external circuit board (not shown). It is also contemplated that the package 210′, as previously described with reference to FIG. 21 and FIG. 22, can be used in place of the bottom package 210.

The middle package 510 is stacked on the bottom package 210, and is implemented with a fan-out configuration as previously described with reference to the package 310 of FIG. 10 through FIG. 18, except that a plurality of solder balls 518b are arranged and mounted on a lower surface of the middle package 510 for forming interconnections with the bottom package 210. It is also contemplated that the middle package 510 can be implemented with a fan-out configuration as previously described with reference to the package 310′ of FIG. 19 and FIG. 20. The top package 320 is stacked on the middle package 510, and is implemented as previously described with reference to FIG. 10. A plurality of solder balls 328b are arranged and mounted on a lower surface of the top package 320 for forming interconnections with the middle package 510.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor package, comprising:
a substrate including an upper surface and a lower surface opposite to the upper surface;
a first chip mounted and electrically connected to the upper surface of the substrate;
an interposer mounted on the first chip and electrically connected to the upper surface of the substrate, the interposer including an upper surface and a lower surface that is opposite to the upper surface and facing the first chip, the interposer including a plurality of electrical contacts located on the upper surface of the interposer; and
a molding compound sealing the substrate, the interposer, and the first chip, and exposing the lower surface of the substrate, the molding compound defining a plurality of holes that enclose and expose respective ones of the electrical contacts.

2. The semiconductor package of claim 1, wherein a lateral boundary of at least one of the holes is tapered.

3. The semiconductor package of claim 2, wherein the at least one of the holes has a wider upper portion and a narrower lower portion.

4. The semiconductor package of claim 3, wherein the at least one of the holes has a cone shape.

5. The semiconductor package of claim 1, wherein at least one of the electrical contacts includes a pad and a conductive bump disposed on the pad.

6. The semiconductor package of claim 1, further comprising:
a second chip mounted and electrically connected to the lower surface of the substrate.

7. A package-on-package device, comprising:
a first semiconductor package including
a first substrate including an upper surface;
a first chip mounted and electrically connected to the upper surface of the first substrate;
a first interposer mounted on the first chip and electrically connected to the upper surface of the first substrate, the first interposer including an upper surface and a lower surface that is opposite to the upper surface and facing the first chip, the first interposer including a plurality of first pads located on the upper surface of the first interposer; and
a first molding compound sealing the first substrate, the first interposer, and the first chip, the first molding compound defining a plurality of first holes corresponding to respective ones of the first pads;
a second semiconductor package stacked on the first semiconductor package, the second semiconductor package including a lower surface facing the first semiconductor package, the second semiconductor package including a plurality of second pads located on the lower surface of the second semiconductor package; and
a plurality of first interconnections extending through respective ones of the first holes of the first molding compound and electrically connecting respective pairs of the first pads and the second pads.

8. The package-on-package device of claim 7, wherein a lateral boundary of at least one of the first holes is tapered.

9. The package-on-package device of claim 7, wherein at least one of the first interconnections corresponds to a pair of fused solder balls.

10. The package-on-package device of claim 7, further comprising:
a third semiconductor package stacked on the second semiconductor package, the third semiconductor package including a lower surface facing the second semiconductor package; and
a plurality of second interconnections electrically connecting the second semiconductor package and the third semiconductor package.

11. The package-on-package device of claim 10, wherein the second semiconductor package includes:
a second substrate including an upper surface;
a second chip mounted and electrically connected to the upper surface of the second substrate;
a second interposer mounted on the second chip and electrically connected to the upper surface of the second substrate, the second interposer including an upper surface and a lower surface that is opposite to the upper surface and facing the second chip, the second interposer including a plurality of third pads located on the upper surface of the second interposer; and
a second molding compound sealing the second substrate, the second interposer, and the second chip, the second molding compound defining a plurality of second holes corresponding to respective ones of the third pads,
wherein the third semiconductor package includes a plurality of fourth pads located on the lower surface of the third semiconductor package,
wherein the second interconnections extend through respective ones of the second holes of the second molding compound and electrically connect respective pairs of the third pads and the fourth pads.

12. The package-on-package device of claim 10, wherein the second semiconductor package includes:
a second substrate including an upper surface and a plurality of third pads located on the upper surface of the second substrate;
a second chip mounted and electrically connected to the upper surface of the second substrate; and
a second molding compound sealing the second substrate and the second chip, the second molding compound defining a plurality of second holes corresponding to respective ones of the third pads,
wherein the third semiconductor package includes a plurality of fourth pads located on the lower surface of the third semiconductor package,
wherein the second interconnections extend through respective ones of the second holes of the second molding compound and electrically connect respective pairs of the third pads and the fourth pads.

13. The package-on-package device of claim 12, wherein the third pads are located adjacent to a periphery of the second substrate.

14. The package-on-package device of claim 13, wherein a thickness of the second molding compound above the third pads is given by H₂, a thickness of the second molding compound above the second chip is given by H₁, and H₂ is smaller than H₁.

15. The package-on-package device of claim 14, wherein H₂ is no greater than ⅔ of H₁.

16. The package-on-package device of claim 14, wherein an interface portion of the second molding compound between H₁ and H₂ defines an angle α, relative to a horizontal plane, that is in the range of 20° to 90°.

17. A manufacturing method, comprising:
providing a substrate including an upper surface;
mounting a chip on the upper surface of the substrate;
mounting an interposer on the chip, the interposer including an upper surface and a lower surface that is opposite to the upper surface and facing the chip, the interposer including a plurality of pads located on the upper surface of the interposer;
applying a molding compound to seal the substrate, the interposer, and the chip; and
forming a plurality of openings in the molding compound, the openings being located so as to correspond to respective ones of the pads of the interposer.

18. The manufacturing method of claim 17, further comprising:
mounting a plurality of conductive bumps on respective ones of the pads of the interposer,
wherein the openings expose respective ones of the conductive bumps.

19. The manufacturing method of claim 18, wherein at least one of the conductive bumps has a width W_{C}, and at least one of the openings has a width W_{U} adjacent to an upper surface of the molding compound, such that W_{U}>W_{C}.

20. The manufacturing method of claim 17, wherein forming the openings is carried out by laser drilling.

21. The manufacturing method of claim 17, wherein forming the openings is carried out by a thickness-decreasing process applied to the molding compound.
